(19) United States
(12) Patent Application Publication
(10) Pub. No.: US 2025/0251639 A1
(43) Pub. Date: Aug. 7, 2025

(54) Optical Device

(71) Applicant: Nippon Telegraph and Telephone Corporation, Tokyo (JP)

(72) Inventors: Kiyofumi Kikuchi, Musashino-shi, Tokyo (JP); Yusuke Nasu, Musashino-shi, Tokyo (JP); Yuriko Kawamura, Musashino-shi, Tokyo (JP)

(21) Appl. No.: 18/855,602

(22) PCT Filed: May 20, 2022
(86) PCT No.: PCT/JP2022/020971

§ 371 Date: Oct. 9, 2024

(51) Int. Cl. G02F 1/21; G02F 1/225; H01S 5/026; H01S 5/50

(52) U.S. Cl. CPC G02F 1/212; G02F 1/225; H01S 5/0265; H01S 5/50

(57) ABSTRACT

Provided is an optical device having a long lifetime and high reliability. An optical device according to one embodiment comprises at least one Mach-Zehnder (MZ) modulator and a redundant semiconductor optical amplifier (SOA). The redundant SOA is connected to at least one MZ modulator via a 2-input 2-output coupler. The redundant SOA includes two SOAs arranged in parallel, and the two SOAs are arranged in two waveguides connected to the 2-input 2-output coupler, respectively. The redundant SOA is configured to switch the two SOAs to amplify light modulated by the at least one MZ modulator or light obtained before modulation.

### TECHNICAL FIELD

The present disclosure relates to an optical device, and more particularly to an optical device comprising a semiconductor amplifier.

### BACKGROUND ART

In the context of a rapid increase in communication demands, extensive studies on large-capacity communication networks are being carried on. For the purpose of increasing the capacity of the communication network, a key is to expand the frequency band of an optical module constituting an optical transmitter and an optical receiver. However, in general, in an optical module and an optical device mounted therein, the frequency band and the photoelectric conversion efficiency are in a trade-off relationship. That is, when the frequency band is expanded in order to increase the capacity of communication, the photoelectric conversion efficiency is lowered accordingly. For example, in the case of an optical transmitter, since the efficiency of converting an electric signal into an optical signal is reduced, the output optical power is reduced. Therefore, a technique for integrating an optical amplifier in an optical transmitter has been extensively studied (see, for example, PTL 1).

### CITATION LIST

### Patent Literature

[PTL 1] Japanese Patent No. 6588851

### SUMMARY OF INVENTION

However, when the optical amplifier and the optical circuit are integrated into one optical device, the life of the optical amplifier determines the life of the entire optical device.

FIG. 1 is a diagram showing a schematic configuration of a general optical device. An optical device 100 shown in FIG. 1 includes one semiconductor optical amplifier (SOA) connected to one Mach-Zehnder (MZ) modulator 101. The MZ modulator 101 is provided with two arm waveguides 104a and 104b connecting a 1-input 2-output coupler 102 and a 2-input 1-output coupler 103, an electrode 105a and an electrode 105b provided in the two arm waveguides 104a and 104b respectively, and a phase shifter 106 provided in at least one of the arm waveguides 104a and 104b. In FIG. 1, electric signals are applied to the electrodes 15a and 15b so that the arm waveguide 104a provided with the electrode 105a becomes a Pos arm and the arm waveguide 104b provided with the electrode 15b becomes a Neg arm.

The light input from the input port of the optical device 100 is branched into two by the 1-input 2-output coupler 102. Thereafter, light modulated by an electric signal applied from the electrode 105a when propagating through the arm waveguide 104a and light modulated by an electric signal applied from the electrode 105b when propagating through the arm waveguide 104b and adjusted in phase by the phase shifter 106 are multiplexed by the 2-input and 1-output coupler 103. The multiplexed light is amplified by the SOA 107 and then output from an output port of the optical device.

In the optical device 100 having the configuration shown in FIG. 1, since the entire optical device does not function when the SOA fails, the life of the SOA determines the life of the entire optical device, resulting in lowered reliability.

The present disclosure has been made in view of the foregoing problems, and an object thereof is to provide an optical device having a long life and high reliability.

To achieve such an object, an optical device of one embodiment of the present disclosure comprises at least one MZ modulator and a redundant SOA, wherein the redundant SOA is connected to the at least one MZ modulator via a 2-input 2-output coupler, includes two SOAs arranged in parallel, the two SOAs being arranged in two waveguides connected to the 2-input 2-output coupler, respectively.

As described above, according to one embodiment of the present disclosure, an optical device having a long life and high reliability.

### BRIEF DESCRIPTION OF DRAWINGS

FIG. 1 is a diagram showing a schematic configuration of an optical device.

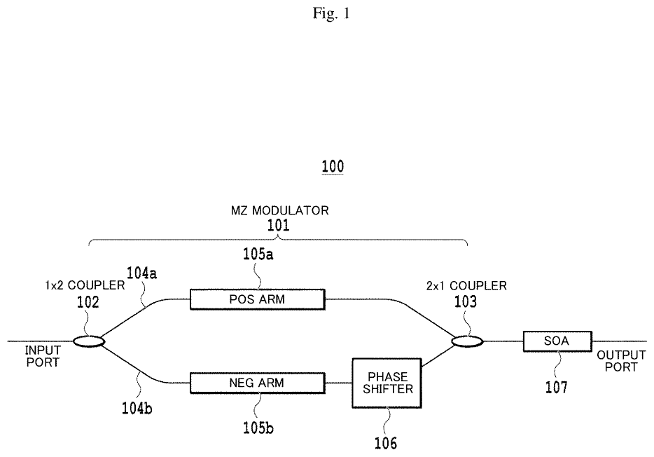

FIG. 2 is a diagram showing a schematic configuration of an optical device according to an embodiment of the present disclosure.

FIG. 3 is a diagram showing a schematic configuration of an optical device according to an embodiment of the present disclosure.

FIG. 4 is a diagram showing a schematic configuration of an optical device according to an embodiment of the present disclosure.

FIG. 5(a) is a diagram showing a schematic configuration of an optical device according to an embodiment of the present disclosure, and FIG. 5(b) is a diagram showing a schematic configuration of an optical device of a reference example.

FIG. 6 is a diagram showing a schematic configuration of an optical device according to an embodiment of the present disclosure.

FIG. 7 is a diagram showing a schematic configuration of an optical device according to an embodiment of the present disclosure.

FIG. 8 is a diagram showing a schematic configuration of an optical device according to an embodiment of the present disclosure.

### DESCRIPTION OF EMBODIMENTS

Embodiments of the present disclosure will now be described below in detail with reference to the drawings. The same or similar signs denote the same or similar elements, and redundant descriptions will be omitted accordingly.

An optical device according to various embodiments of the present disclosure includes a modulator of an MZ (also simply referred to as an MZ modulator) and two SOAs (also simply referred to as a redundant SOA) with a redundant configuration that is connected to the MZ modulator via a 2-input 2-output coupler. The optical device according to one embodiment of the present disclosure further comprises a variable attenuator (VOA). The MZ modulator, the redundant SOA, and the VOA are integrated on a waveguide substrate to constitute the optical device. In the present disclosure, a coupler having M inputs and N outputs is called an M-input N-output coupler or an M×N coupler, where M and N are integers. The coupler can be a directional coupler, a multimode interference (MMI) coupler, a branch waveguide, or a cross waveguide.

According to the configuration of the optical device according to various embodiments of the present disclosure, even if one of the redundant SOA fails, the optical device can be switched to the other, prolonging the life of the optical device and improving the reliability.

### Embodiment 1

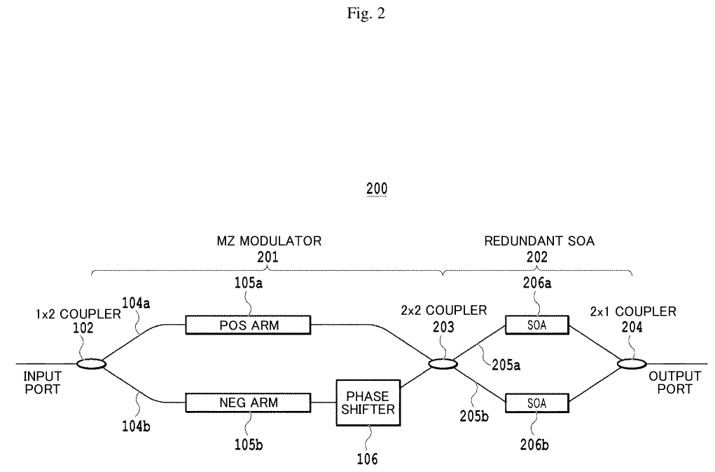

FIG. 2 is a diagram showing a schematic configuration of an optical device according to an embodiment of the present invention. An optical device 200 shown in FIG. 2 is provided with a 1-input 2-output coupler 102, a 2-input 2-output coupler 203, a 2-input 1-output coupler 204, an arm waveguide 104a and an arm waveguide 104b for connecting the 1-input 2-output coupler 102 and the 2-input 2-output coupler 203, and an arm waveguide 205a and an arm waveguide 205b for connecting the 2-input 2-output coupler 203 and the 2-input 1-output coupler 204.

The arm waveguide 104a is provided with an electrode 105a, and the arm waveguide 104b is provided with an electrode 105b and a phase shifter 106.

The arm waveguide 205a is provided with an SOA 206a, and the arm waveguide 205b is provided with an SOA 206a.

The 1-input 2-output coupler 102, the 2-input 2-output coupler 203, the arm waveguide 104a, the arm waveguide 104b, the electrode 105a, the electrode 105b, and the phase shifter 106 constitute an MZ modulator 201. The arm waveguide 104a and the arm waveguide 104b are configured to have the same length.

The 2-input 2-output coupler 203, the 2-input 1-output coupler 204, the arm waveguide 205a, the arm waveguide 205b, the SOA 206a, and the SOA 206b constitute the redundant SOA 202. The arm waveguide 205a and the arm waveguide 205b are configured to have the same length. The redundant SOA 202 is configured so that a current or voltage is applied to the SOA 206a when amplifying light propagating through the arm waveguide 205a, and that a current or voltage is applied to the SOA 206b when amplifying light propagating through the arm waveguide 205b.

The light input from an input port of the optical device 200 is branched into two by the 1-input 2-output coupler 102. Light propagating through the arm waveguide 104a is modulated by an electric signal applied from the electrode 105a. Light propagating through the arm waveguide 104b is modulated by an electric signal applied from the electrode 105b and then adjusted in phase by the phase shifter 106. The light propagated through the arm waveguide 104a and the light propagated through the arm waveguide 104b are made incident on the 2-input 2-output coupler 203, multiplexed, and branched again into two light beams.

The light branched into two by the 2-input 2-output coupler 203 is propagated through the arm waveguide 205a and the arm waveguide 205b, respectively. For example, a current or a voltage is applied to only one of the SOA 206a and the SOA 206b, to amplify light output from an output port of the optical device 200. The amplified light is output from the output port of the optical device 200 via the 2-input 1-output coupler 204. When one of the SOA 206a and the SOA 206b to which the current or the voltage is applied fails, the application of the current or the voltage is switched to the other one of the SOA 206a and the SOA 206b, thereby continuing the amplification of the light output from the output port of the optical device 200.

According to the configuration of the optical device of the present embodiment, the life of the optical device is prolonged and the reliability is improved.

In the configuration of the present embodiment, when one of the two outputs of the 2-input 2-output coupler 203 constituting the MZ modulator 201 is not used, the effective use of it can suppress the increase in the number of components of the optical device 200.

The optical device 200 having a configuration in which the redundant SOA amplifies the light modulated by the MZ modulator 201 has been described with reference to FIG. 2, but a configuration is possible in which the MZ modulator 201 modulates the light amplified by the redundant SOA.

### Second Embodiment

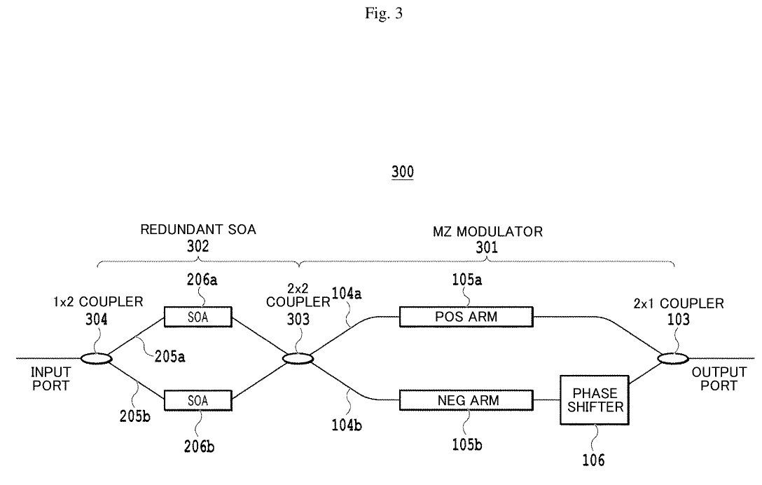

FIG. 3 is a diagram showing a schematic configuration of an optical device according to an embodiment of the present invention. An optical device 300 shown in FIG. 3 differs from the optical device shown in FIG. 2 in that the MZ modulator modulates the light amplified by the redundant SOA, and that the redundant SOA amplifies the light modulated by the MZ modulator.

The optical device 300 shown in FIG. 3 is provided with a 1-input 2-output coupler 304, a 2-input 2-output coupler 303, a 2-input 1-output coupler 103, an arm waveguide 205a and an arm waveguide 205b connecting the 1-input 2-output coupler 304 and the 2-input 2-output coupler 303, and an arm waveguide 104a and an arm waveguide 104b connecting the 2-input 2-output coupler 303 and the 2-input 1-output coupler 103.

The arm waveguide 205a is provided with an SOA 206a, and the arm waveguide 205b is provided with an SOA 206b.

The arm waveguide 104a is provided with an electrode 105a, and the arm waveguide 104b is provided with an electrode 105b and a phase shifter 106.

The 2-input 2-output coupler 303, the 2-input 1-output coupler 103, the arm waveguide 104a, the arm waveguide 104b, the electrode 105b, the electrode 105b, and the phase shifter 106 constitute an MZ modulator 301. The configuration of the MZ modulator 301 is the same as that of the MZ modulator 201 except for the number of inputs of the 2-input 2-output coupler 303 and the number of outputs of the 2-input 1-output coupler 103.

The 1-input 2-output coupler 304, the 2-input 2-output coupler 303, the arm waveguide 205a, the arm waveguide 205b, the SOA 206a, and the SOA 206b constitute a redundant SOA 302. The configuration of the redundant SOA 302 is the same as that of the redundant SOA 202 except for the number of inputs of the 1-input 2-output coupler 304 and the number of outputs of the 2-input 2-output coupler 303.

Light input from an input port of the optical device 300 is uniformly distributed to the arm waveguide 205a and the arm waveguide 205b by the 1-input 2-output coupler 304. For example, light can be amplified by applying a current or a voltage only to one of the SOA 206a and SOA 206b.

The light amplified by the redundant SOA 302, that is, the two light beams branched by the 2-input 2-output coupler 303, are propagated through the arm waveguide 104a and the arm waveguide 104b, respectively, made incident on the 2-input 1-output coupler 103, multiplexed, and output from an output port of the optical device 300.

According to the configuration of the optical device 300 of the present embodiment, when one of the SOA 206a and the SOA 206b to which the current or the voltage is applied fails, the application of the current or the voltage is switched to the other one of the SOA 206a and the SOA 206b, thereby continuing the amplification of the light output from the output port of the optical device 300.

In the redundant SA 301, since the other one of the SOA 206a and the SOA 206b to which no current or voltage is applied absorbs light, the light propagating through the corresponding arm waveguide 205a or the arm waveguide 205b becomes lost. In the configuration of the optical device 300 of the present embodiment, when the power of light incident on the input port of the optical device 300 is large, a loss of 3 dB in the 1-input 2-output coupler 304 and the characteristic of the redundant SOA 302 do not deteriorate the SN ratio (OSNR) of light in the optical device 300.

Since the optical device 300 of the present embodiment functions as an attenuator when application of a current or a voltage is stopped in the redundant SOA 302, the optical device 300 can also be used as a shutter having a function of shutting down light.

The optical device 300 of the present embodiment also has a longer life and higher reliability as with the optical device 200.

### Embodiment 3

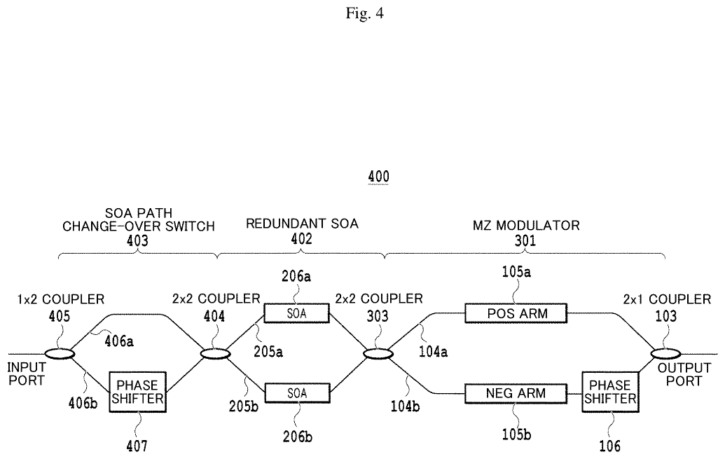

FIG. 4 is a diagram showing a schematic configuration of an optical device according to an embodiment of the present invention. Even when the power of light incident on an input port of an optical device 400 shown in FIG. 4 is small, the optical device 400 can amplify the light without deteriorating the OSNR.

The optical device 400 of FIG. 4 includes a redundant SOA 402 connected to the MZ modulator 301. In the redundant SOA 402, the 1-input 2-output coupler 303 is replaced with a 2-input 2-output coupler 404 in the configuration of the redundant SOA 302 of the optical device 300 shown in FIG. 3. The optical device 400 shown in FIG. 4 further includes an SOA path change-over switch 403 connected to the front stage of the 2-input 2-output coupler 404.

The MZ modulator 301 has the same configuration as the MZ modulator 301 of the optical device 300 shown in FIG. 3.

The 2-input 2-output coupler 404, the 2-input 2-output coupler 303, the arm waveguide 205a, the arm waveguide 205b, the SOA 206a, and the SOA 206b constitute a redundant SOA 402. The configuration of the redundant SOA 402 is the same as that of the redundant SOA 302 except for the number of inputs of the 2-input 2-output coupler 404.

A 1-input 2-output coupler 405, the 2-input 2-output coupler 404, an arm waveguide 406a, an arm waveguide 406b, and a phase shifter 407 constitute the SOA path change-over switch 403.

The 1-input 2-output coupler 405 branches light made incident from the input port of the optical device 400, into the arm waveguide 406a and the arm waveguide 406b.

The arm waveguide 406a and the arm waveguide 406b are configured to have the same length.

The phase shifter 407 modulates the phase of light propagating through the arm waveguide 404b according to the applied current or voltage.

The 2-input 2-output coupler 404 multiplexes the arm waveguide 404a and the arm waveguide 404b and distributes them to the arm waveguides 205a and 205b of the redundant SOA 402. At this time, the ratio of the light distributed to the arm waveguides 205a and 205b changes according to the phase of the light propagating through the arm waveguide 404b. That is, the optical device 400 of the present embodiment can control the ratio of light to be distributed to the arm waveguide 205a and the arm waveguide 205b in the 2-input 2-output coupler 404 by controlling the current or voltage applied to the phase shifter 407 of the SOA path change-over switch 403. For example, in the case of amplifying light by applying a current or voltage to the SOA 206a in the redundant SOA 402, the ratio of light to be distributed to the arm waveguide 205a is increased and the ratio of light to be distributed to the arm waveguide 205b is decreased, thereby the loss of light in the redundant SOA 402 can be reduced.

As described above, the optical device 400 of the present embodiment has a longer life and higher reliability as with the optical device 300. Also, even when the power of light incident on the input port of the optical device 400 is small, the optical device 400 can amplify the light without deteriorating the OSNR.

### Embodiment 4

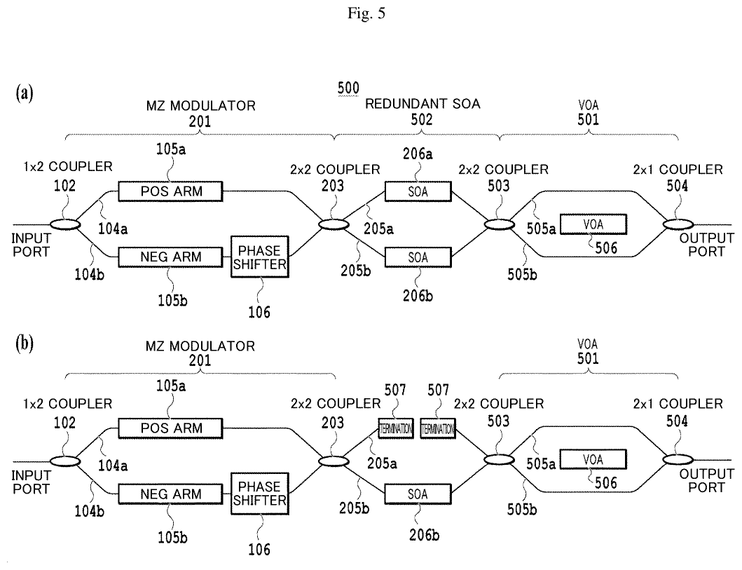

FIG. 5(a) is a diagram showing a schematic configuration of an optical device according to an embodiment of the present disclosure. An optical device 500 shown in FIG. 5 has a configuration in which a variable attenuator (VOA) is connected to the subsequent stage of the redundant SAO 202 of the optical device 200 shown in FIG. 2.

In a redundant SOA 502 in the optical device 500 of FIG. 5(a), the 2-input 1-output coupler 204 of the redundant SOA 202 of FIG. 2 is replaced with a 2-input 2-output coupler 503. The optical device 500 shown in FIG. 5(a) further includes a VOA 501 connected to the subsequent stage of the 2-input 2-output coupler 503.

The MZ modulator 201 has the same configuration as the MZ modulator 201 of the optical device 200 shown in FIG. 2.

The 2-input 2-output coupler 203, the 2-input 2-output coupler 503, the arm waveguide 205a, the arm waveguide 205b, the SOA 206a, and the SOA 206b constitute the redundant SOA 502. The configuration of the redundant SOA 502 is the same as that of the redundant SOA 202 except for the number of outputs of the 2-input 2-output coupler 503.

The 2-input 2-output coupler 503, a 2-input 1-output coupler 504, an arm waveguide 505a, an arm waveguide 505b, and a VOA electrode 506 constitute a VOA 501. The arm waveguide 505a and the arm waveguide 505b are configured to have the same length. In the VOA 501, the intensity of light output from an output port of the optical device 500 via the 2-input 1-output coupler 504 changes according to a current or a voltage applied to the VOA electrode 506.

FIG. 5(b) is a diagram showing a schematic configuration of an optical device of a reference example. As shown in FIG. 5(b), when the SOA is interposed between the MZ modulator 201 and the VOA 501, the SOA (206b in FIG. 5(b)) is provided in a waveguide connecting one of two outputs of the 2-input 2-output coupler 203 and one of two inputs of the 2-input 2-output coupler, and the other one of the two outputs of the 2-input 2-output coupler 203 and the other one of the two inputs of the 2-input 2-output coupler are terminated. In the case of the configuration as shown in FIG. 5(b), the other one of the two outputs of the 2-input 2-output coupler 203 and the other one of the two inputs of the 2-input 2-output coupler are not terminated but connected by the arm waveguide 205a as shown in FIG. 5(a) to provide the SOA 206a, thereby configuring the redundant SOA without suppressing an increase in the number of components of the optical device.

In the optical device 500 of the present embodiment as well, the life of the optical device becomes long and the reliability becomes high.

### Embodiment 5

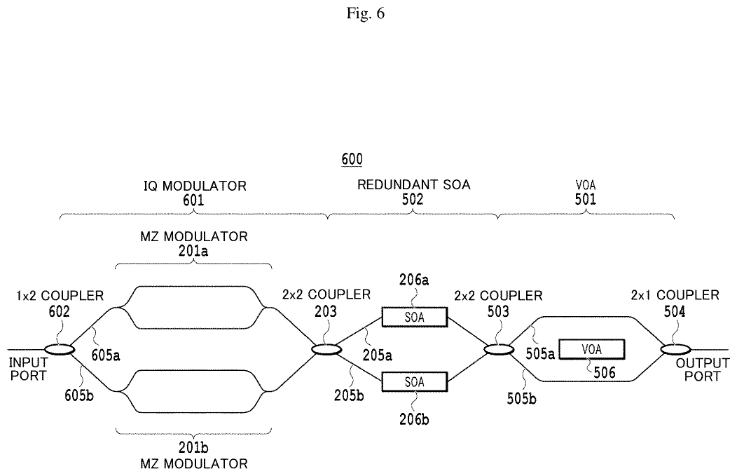

FIG. 6 is a diagram showing a schematic configuration of an optical device according to an embodiment of the present disclosure. An optical device 600 shown in FIG. 6 has a configuration in which the single MZ modulator 201 connected to the front stage of the redundant SOA 502 of the optical device 500 shown in FIG. 5(a) is replaced with two MZ modulators 201a and 201b arranged in parallel.

The optical device of FIG. 6 includes arm waveguides 605a and 605b connecting a 1-input 2-output coupler 602 and a 2-input 2-output coupler 203, the MZ modulator 201a connected to the arm waveguide 605a, and the MZ modulator 201b connected to the arm waveguide 605b.

The 1-input 2-output coupler 602, the 2-input 2-output coupler 203, the arm waveguides 605a and 605b, and the MZ modulator 201a and the MZ modulator 201b constitute an IQ modulator 601.

As shown in FIG. 6, a redundant SOA 505 can be easily disposed at the subsequent stage of the 2-input 2-output coupler 203 on the output side of the IQ modulator 601, prolonging the life of the optical device and improving the reliability thereof.

In the present embodiment, the redundant SOA is disposed at the subsequent stage of the IQ modulator, but the redundant SOA can also be disposed at the front stage of the IQ modulator 601.

### Embodiment 6

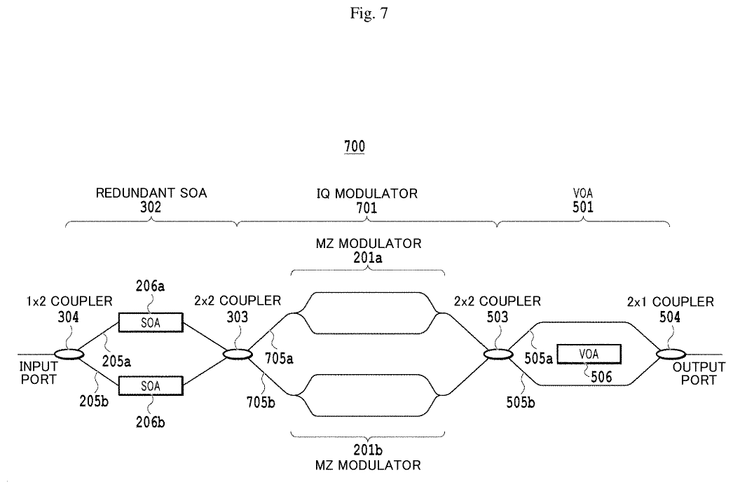

FIG. 7 is a diagram showing a schematic configuration of an optical device according to an embodiment of the present disclosure. An optical device 700 shown in FIG. 7 is different from the optical device 600 shown in FIG. 6 in that a redundant SOA is arranged in the front stage of an IQ modulator.

The optical device 700 of FIG. 7 includes the redundant SOA 302 described with reference to FIG. 3, the VOA 501 described with reference to FIG. 5, arm waveguides 705a and 705b connecting the 2-input 2-output coupler 303 and the 2-input 2-output coupler 503, an MZ modulator 201a connected to the arm waveguide 705a, and an MZ modulator 201b connected to the arm waveguide 605b. The lengths of the arm waveguides 705a and 705b are constituted equally.

The configuration of the optical device 700 shown in FIG. 7 also has a long life and high reliability, as with the optical device 600.

### Embodiment 7

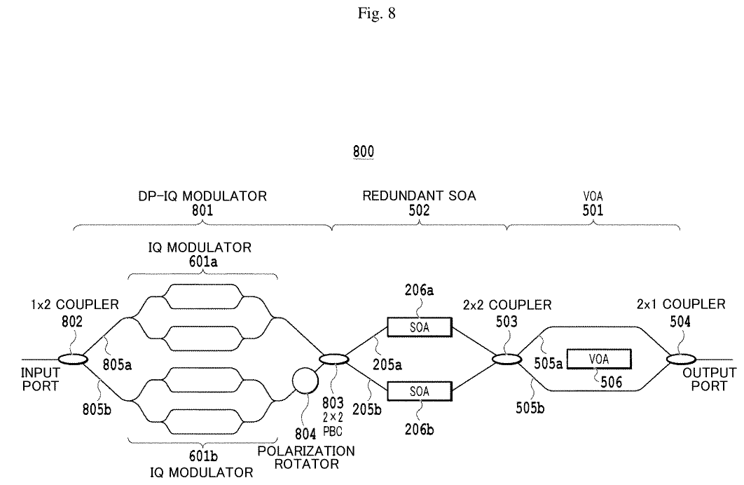

FIG. 8 is a diagram showing a schematic configuration of an optical device according to an embodiment of the present disclosure. An optical device 800 shown in FIG. 8 is different from the optical device 500 shown in FIG. 5 in that two IQ modulators 601a and 601b arranged in parallel are arranged at the front stage of the redundant SOA 502 of the optical device 500 shown in FIG. 5(a).

A 1-input 2-output coupler 802, a 2-input 2-output polarization beam combiner (PBC) 803, arm waveguides 805a and 805b connecting the 1-input 2-output coupler 802 and the 2-input 2-output PBC 803, an IQ modulator 601a connected to the arm waveguide 805a, an IQ modulator 601b and a polarization rotator 804 connected to the arm waveguide 805b constitute a DP-IQ (Dual Polarization In-phase Quadrature) modulator 801. The lengths of the arm waveguides 805a and 805b are equal. In the present embodiment, the 2-input 2-output polarization beam combiner (PBC) 803 functions as a 2-input 2-output coupler for connecting the MZ modulator and the redundant SOA.

The configuration of the optical device 800 shown in FIG. 8 also has a long life and high reliability, as with the optical device 500.

### INDUSTRIAL APPLICABILITY

According to the present disclosure, the life of an optical device can be prolonged, and an optical device having high reliability can be provided.

### REFERENCE SIGNS LIST

100, 200, 300, 400, 500, 600, 700, 800 Optical device
102, 304, 405, 802 1-input 2-output coupler
104a, 104b, 205a, 205b, 406a, 406b, 505a, 505b, 805a, 805b Arm waveguide
105a, 105b Electrode
106, 407 Phase shifter
201, 301 MZ modulator
202, 302, 402, 502 Redundant SOA
203, 303, 404, 503 2-input 2-output coupler
204, 504 2-input 1-output coupler
206a, 206b SOA
403 SOA path change-over switch
501 Variable attenuator (VOA)
506 VOA electrode
507 Termination
601, 601a, 601b, 701 IQ modulator
801 DP-IQ modulator
803 2-input 2-output PCB
804 Polarization rotator

1. An optical device, comprising:
at least one Mach-Zehnder modulator; and
a redundant semiconductor optical amplifier (SOA),
wherein the redundant SOA is connected to the at least one MZ modulator via a 2-input 2-output coupler,
the redundant SOA includes two SOAs arranged in parallel, and
the two SOAs are arranged in two waveguides connected to the 2-input 2-output coupler, respectively.

2. The optical device according to claim 1, wherein the redundant SOA is configured to switch the two SOAs to amplify light modulated by the at least one MZ modulator or light obtained before modulation.

3. The optical device according to claim 1, wherein the 2-input 2-output coupler is configured to distribute light modulated by the at least one MZ modulator to the two waveguides.

4. The optical device according to claim 1, wherein the 2-input 2-output coupler is configured to distribute light from the two waveguides to which the two SOAs are connected, to two arm waveguides of the at least one MZ modulator.

5. The optical device according to claim 4, further comprising a change-over switch configured to input light into one of the two waveguides to which the two SOAs are connected.

6. The optical device according to claim 1, further comprising a variable attenuator (VOA) connected to the redundant SOA.

7. The optical device according to claim 1, wherein the number of the at least one MZ modulator is two.

8. The optical device according to claim 1, wherein the number of the at least one MZ modulator is four and the 2-input 2-output coupler is a 2-input 2-output polarization beam combiner.
